(19) United States
(12) Patent Application Publication
(10) Pub. No.: US 2024/0237247 A1
(43) Pub. Date: Jul. 11, 2024

(54) FOLDABLE SHEET AND ELECTRONIC DEVICE INCLUDING SAME

(71) Applicant: SAMSUNG ELECTRONICS CO., LTD., Suwon-si (KR)

(72) Inventors: Yongwoon KIM, Suwon-si (KR); Eunsoo PARK, Suwon-si (KR); Doyun KIM, Suwon-si (KR); Jonghoon WOO, Suwon-si (KR)

(21) Appl. No.: 18/618,428

(22) Filed: Mar. 27, 2024

Related U.S. Application Data
(63) Continuation of application No. PCT/KR2022/011169, filed on Jul. 29, 2022.

(30) Foreign Application Priority Data
Sep. 27, 2021 (KR) 10-2021-0126916
Oct. 27, 2021 (KR) 10-2021-0144311

(51) Int. Cl. H05K 5/03; H05K 5/02

(52) U.S. Cl. CPC H05K 5/03; H05K 5/0226

(57) ABSTRACT

A foldable sheet of an embodiment may include a body area including a first body and a second body spaced apart from the first body, a folding area positioned between the first body and the second body and folded in a first direction so that the first body and the second body face each other, a bending area including a first bending area for connecting one end of the folding area and the first body, and a second bending area for connecting the other end of the folding area and the second body. The bending area may have a structure which is bent at least twice to protrude in a second direction opposite to the first direction so that the first body and the second body are arranged in parallel to each other in a state where the folding area is unfolded.

### CROSS-REFERENCE TO RELATED APPLICATIONS

This application is a continuation of International Application No. PCT/KR2022/011169 designating the United States, filed on Jul. 29, 2022, in the Korean Intellectual Property Receiving Office and claiming priority to Korean Patent Application Nos. 10-2021-0126916, filed on Sep. 27, 2021, and 10-2021-0144311, filed on Oct. 27, 2021, in the Korean Intellectual Property Office, the disclosures of each of which are incorporated by reference herein in their entireties.

### TECHNICAL FIELD

Various embodiments described herein relates to a foldable sheet and an electronic device including the foldable sheet.

### BACKGROUND ART

As electronic devices are gradually becoming slimmer, efforts are being made to improve the rigidity of electronic devices, strengthen design aspects, and differentiate their functional elements. Electronic devices are gradually being transformed into various shapes from their typical uniform rectangular shape. There has been research to find a way to implement a deformable structure that is conveniently portable and at the same time uses a large screen display, and there is thus a growing interest in a foldable device including at least two foldable housings that operate by being folded or unfolded with respect to each other.

An electronic device may include a foldable display that is at least partially foldable to provide a user with a wide display and ensure portability. The electronic device may include a hinge unit, a first housing and a second housing connected to the hinge unit, a foldable display panel connected to the first housing and the second housing, and a foldable sheet connected to the back of the foldable display panel to provide flexibility and rigidity. Accordingly the first housing and the second housing may be folded with respect to the hinge unit in an in-folding and/or out-folding manner in a range between 0 degrees indicating an unfolded state and 360 degrees.

### DISCLOSURE OF INVENTION

### Technical Goals

A foldable sheet may include a folding area in which a lattice pattern including a plurality of slits is formed to facilitate folding and an unfolding area connected to both sides of the folding area., A space may be provided on the back of the folding area for the foldable sheet to be deformed.

Overtime, the foldable sheet may encounter problems. For example, a fine deformation may occur where the foldable sheet is used or continuously repeated folding operations, and there may also be a crease generated near the folding area by the accumulation of plastic deformations. The crease of the foldable sheet may be generated repeatedly on both sides of the folding area as some areas are raised in the shape of a camel's back (e.g., a hump), which causes a potentially permanent deformation. As a result, it may form a curve in the display panel of the electronic device, thereby causing the user to experience a relatively rough touch feel, generating the bending of reflected light, and deteriorating the satisfaction with the external appearance.

The objective of embodiments of the present disclosure is to provide a foldable sheet having a structure that may prevent or suppress a crease, and an electronic device including the foldable sheet.

The technical goals and objectives achievable by various embodiments disclosed herein are not limited to those described above, but other technical goals and objectives not described above may also be clearly understood by those having ordinary skill in the art to which the present disclosure pertains from the following description.

### Technical Solutions

According to an embodiment of the present disclosure, there is provided a foldable sheet including: a body area including a first body and a second body spaced apart from the first body; a folding area disposed between the first body and the second body and folded in a first direction such that the first body and the second body face each other; and a bending area including a first bending area connecting one end of the folding area and the first body and a second bending area connecting the other end of the folding area and the second body. In an embodiment, the bending area may be provided in a structure that is bent at least twice to protrude in a second direction opposite to the first direction to allow the first body and the second body to be arranged in parallel when the folding area is in an unfolded state.

According to another embodiment of the present disclosure, there is provided an electronic device including: a hinge unit that is folded in a folding direction and is unfolded in an unfolding direction; a pair of housings coupled to the hinge unit to be folded in opposite directions with respect to the hinge unit; and a foldable sheet connected to one surface of the pair of housings in the folding direction. In an embodiment, the foldable sheet may include: a body area including a first body and a second body spaced apart to be respectively connected to the pair of housings; a folding area disposed between the first body and the second body and folded in conjunction with the hinge unit; and a bending area including a first bending area connecting one end of the folding area and the first body and a second bending area connecting the other end of the folding area and the second body. In an embodiment, the bending area may be provided in a structure that is bent at least twice to protrude in the unfolding direction to allow the first body and the second body to be arranged in parallel when the folding area is unfolded.

### Effects

An embodiment of the present disclosure provides a foldable sheet and an electronic device including the foldable sheet, which may prevent a crease of the foldable sheet, suppress deformation in the electronic device by the crease, and implement smooth folding.

According to the embodiment of the present disclosure, the foldable sheet may have a gap formed by a bending area to improve deformation flexibility and improve accuracy in coupling with other devices such as a display panel.

In addition, other various effects that may be identified directly or indirectly through the present disclosure may also be provided.

### BRIEF DESCRIPTION OF DRAWINGS

FIG. 1 is a block diagram illustrating an electronic device in a network environment according to various embodiments.

FIG. 2A is a plan view of an electronic device according to an embodiment.

FIG. 2B is a rear view of an electronic device according to an embodiment.

FIG. 2C is a plan view of an electronic device according to an embodiment.

FIG. 2D is a rear view of an electronic device according to an embodiment.

FIG. 2E is a side view of an electronic device according to an embodiment.

FIG. 3A is an exploded perspective view of an electronic device according to an embodiment.

FIG. 3B is an exploded perspective view of a hinge unit according to an embodiment.

FIG. 4 is a perspective view of a foldable sheet according to an embodiment.

FIG. 5 is a perspective view of a foldable sheet according to an embodiment.

FIG. 6 is a perspective view of a foldable sheet according to an embodiment.

FIG. 7A is a diagram illustrating one of folding states of a foldable sheet according to an embodiment.

FIG. 7B is a diagram illustrating one of folding states of a foldable sheet according to an embodiment.

FIG. 7C is a diagram illustrating one of folding states of a foldable sheet according to an embodiment.

FIG. 8 is a perspective view of a foldable sheet according to an embodiment.

FIG. 9 is a cross-sectional view of an electronic device according to an embodiment.

FIG. 10 is a diagram illustrating one of folding states of a foldable sheet according to an embodiment.

FIG. 11 is a diagram illustrating one of folding states of a foldable sheet according to an embodiment.

### BEST MODE FOR CARRYING OUT INVENTION

Hereinafter, various embodiments will be described in greater detail with reference to the accompanying drawings. When describing the embodiments with reference to the accompanying drawings, like reference numerals refer to like elements and a repeated description related thereto will be omitted.

It is to be understood that various embodiments of the disclosure and the terms used therein are not intended to limit the technological features set forth herein to some particular embodiments but include various changes, equivalents, or replacements for a corresponding embodiment. In connection with the description of the drawings, like reference numerals may be used for similar or related components. It is to be understood that a singular form of a noun corresponding to an item may include one or more of the things unless the relevant context clearly indicates otherwise. As used herein, “A or B,” “at least one of A and B,” “at least one of A or B,” “A, B, or C,” “at least one of A, B, and C,” and “at least one of A, B, or C,” each of which may include any one of the items listed together in the corresponding one of the phrases, or all possible combinations thereof. Terms such as “1st” and “2nd” or “first” and “second” may simply be used to distinguish the component from other components in question, and do not limit the components in other aspects (e.g., importance or order). It is to be understood that if an element (e.g., a first element) is referred to, with or without the term “operatively” or “communicatively,” as “coupled with,” “coupled to,” “connected with,” or “connected to” another element (e.g., a second element), it denotes that the element may be coupled with the other element directly (e.g., by wire), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in the form of an application-specific integrated circuit (ASIC).

Various embodiments as set forth herein may be implemented as software (e.g., a program) including one or more instructions that are stored in a storage medium (e.g., an internal memory or an external memory) that is readable by a machine (e.g., an electronic device). For example, a processor of the machine may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply denotes that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method described herein may be included and provided in a computer program product. The computer program product may be traded as a product between a seller and a buyer. The computer program product may be distributed in the form of a machine-readable storage medium (e.g., a compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as a memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

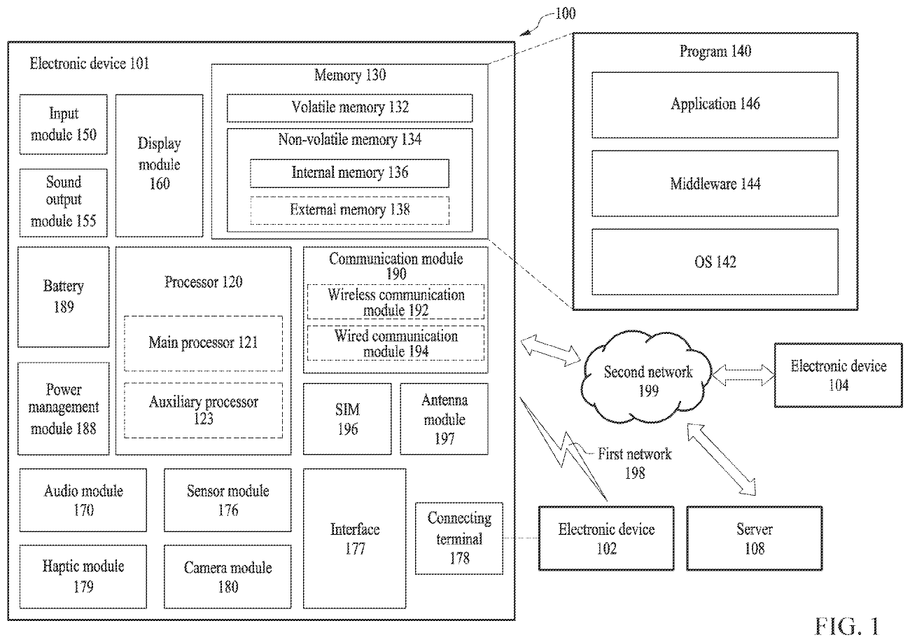

FIG. 1 is a block diagram illustrating an electronic device 101 in a network environment 100 according to an embodiment. Referring to FIG. 1, the electronic device 101 in the network environment 100 may communicate with an electronic device 102 via a first network 198 (e.g., a short-range wireless communication network), or communicate with at least one of an electronic device 104 and a server 108 via a second network 199 (e.g., a long-range wireless communication network). The electronic device 101 may communicate with the electronic device 104 via the server 108. The electronic device 101 may include a processor 120, a memory 130, an input module 150, a sound output module 155, a display module 160, an audio module 170, and a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one (e.g., the connecting terminal 178) of the above components may be omitted from the electronic device 101, or one or more other components may be added to the electronic device 101. In some embodiments, some (e.g., the sensor module 176, the camera module 180, or the antenna module 197) of the components may be integrated as a single component (e.g., the display module 160).

The processor 120 may execute, for example, software (e.g., a program 140) to control at least one other component (e.g., a hardware or software component) of the electronic device 101 connected to the processor 120, and may perform various data processing or computation. According to an embodiment, as at least a part of data processing or computation, the processor 120 may store a command or data received from another component (e.g., the sensor module 176 or the communication module 190) in a volatile memory 132, process the command or data stored in the volatile memory 132, and store resulting data in a non-volatile memory 134. The non-volatile memory 134 may include internal memory 136 and/or external memory 138. The processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently from or in conjunction with, the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state or along with the main processor 121 while the main processor 121 is an active state (e.g., executing an application). The auxiliary processor 123 (e.g., an ISP or a CP) may be implemented as a portion of another component (e.g., the camera module 180 or the communication module 190) that is functionally related to the auxiliary processor 123. The auxiliary processor 123 (e.g., an NPU) may include a hardware structure specifically for artificial intelligence (AI) model processing. An AI model may be generated by machine learning. The learning may be performed by, for example, the electronic device 101, in which the AI model is performed, or performed via a separate server (e.g., the server 108). Learning algorithms may include, but are not limited to, for example, supervised learning, unsupervised learning, semi-supervised learning, or reinforcement learning. The AI model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), and a bidirectional recurrent deep neural network (BRDNN), a deep Q-network, or a combination of two or more thereof, but is not limited thereto. The AI model may alternatively or additionally include a software structure other than the hardware structure.

The memory 130 may store various pieces of data used by at least one component (e.g., the processor 120 or the sensor module 176) of the electronic device 101. The various pieces of data may include, for example, software (e.g., the program 140) and input data or output data for a command related thereto. The memory 130 may include the volatile memory 132 or the non-volatile memory 134.

The program 140 may be stored as software in the memory 130 and may include, for example, an operating system (OS) 142, middleware 144, or an application 146.

The input module 150 may receive, from outside (e.g., a user) the electronic device 101, a command or data to be used by another component (e.g., the processor 120) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for general purposes, such as playing multimedia or playing a recording. The receiver may be used to receive an incoming call. The receiver may be implemented separately from the speaker or as a part of the speaker.

The display module 160 may visually provide information to the outside (e.g., a user) of the electronic device 101. The display module 160 may include, for example, a display, a hologram device, or a projector, and a control circuitry to control its corresponding one of the displays, the hologram device, and the projector. The display module 160 may include a touch sensor adapted to sense a touch, or a pressure sensor adapted to measure an intensity of a force of the touch.

The audio module 170 may convert sound into an electric signal or vice versa. The audio module 170 may obtain the sound via the input module 150 or output the sound via the sound output module 155 or an external electronic device (e.g., the electronic device 102, such as a speaker or headphones) directly or wirelessly connected to the electronic device 101.

The sensor module 176 may detect an operational state (e.g., power or temperature) of the electronic device 101 or an environmental state (e.g., a state of a user) external to the electronic device 101 and generate an electric signal or data value corresponding to the detected state. The sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used by the electronic device 101 to couple with an external electronic device (e.g., the electronic device 102) directly (e.g., by wire) or wirelessly. The interface 177 may include, for example, a high-definition multimedia interface (HDMI), a universal serial bus (USB) interface, a secure digital (SD) card interface, or an audio interface.

The connecting terminal 178 may include a connector via which the electronic device 101 may physically connect to an external electronic device (e.g., the electronic device 102). The connecting terminal 178 may include, for example, an HDMI connector, a USB connector, an SD card connector, or an audio connector (e.g., a headphones connector).

The haptic module 179 may convert an electric signal into a mechanical stimulus (e.g., a vibration or a movement) or an electrical stimulus, which may be recognized by a user via their tactile sensation or kinesthetic sensation. The haptic module 179 may include, for example, a motor, a piezoelectric element, or an electric stimulator.

The camera module 180 may capture a still image and moving images. The camera module 180 may include one or more lenses, image sensors, ISPs, and flashes.

The power management module 188 may manage power supplied to the electronic device 101. The power management module 188 may be implemented as, for example, at least a part of a power management integrated circuit (PMIC).

The battery 189 may supply power to at least one component of the electronic device 101. The battery 189 may include, for example, a primary cell, which is not rechargeable, a secondary cell, which is rechargeable, or a fuel cell.

The communication module 190 may support establishing a direct (e.g., wired) communication channel or a wireless communication channel between the electronic device 101 and an external electronic device (e.g., the electronic device 102, the electronic device 104, or the server 108) and performing communication via the established communication channel. The communication module 190 may include one or more CPs that are operable independently from the processor 120 (e.g., an AP) and that support direct (e.g., wired) communication or wireless communication. The communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device, for example, the electronic device 104, via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5^{th} generation (5G) network, a next-generation communication network, the Internet, or a computer network (e.g., an LAN or a wide area network (WAN)). These various types of communication modules may be implemented as a single component (e.g., a single chip), or may be implemented as multiple components (e.g., multiple chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4^{th} generation (4G) network, and a next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., an mmWave band) to achieve, e.g., a high data transmission rate. The wireless communication module 192 may support various technologies for securing performance on a high-frequency band, such as, e.g., beamforming, massive multiple-input and multiple-output (MIMO), full dimensional MIMO (FD-MIMO), an array antenna, analog beamforming, or a large-scale antenna. The wireless communication module 192 may support various requirements specified in the electronic device 101, an external electronic device (e.g., the electronic device 104), or a network system (e.g., the second network 199). The wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., an external electronic device) of the electronic device 101. The antenna module 197 may include an antenna including a radiating element including a conductive material or a conductive pattern formed in or on a substrate (e.g., a printed circuit board (PCB)). The antenna module 197 may include a plurality of antennas (e.g., an antenna array). In such a case, at least one antenna appropriate for a communication scheme used in a communication network, such as the first network 198 or the second network 199, may be selected by, for example, the communication module 190 from the plurality of antennas. The signal or power may be transmitted or received between the communication module 190 and the external electronic device via the at least one selected antenna. According to an embodiment, another component (e.g., a radio frequency integrated circuit (RFIC)) other than the radiating element may be additionally formed as a part of the antenna module 197.

According to various embodiments, the antenna module 197 may form an mmWave antenna module. The mmWave antenna module may include a PCB, an RFIC on a first surface (e.g., a bottom surface) of the PCB or adjacent to the first surface of the PCB and capable of supporting a designated high-frequency band (e.g., a mmWave band), and a plurality of antennas (e.g., an antenna array) disposed on a second surface (e.g., a top or a side surface) of the PCB, or adjacent to the second surface of the PCB and capable of transmitting or receiving signals in the designated high-frequency band.

At least some of the above-described components may be coupled mutually and exchange signals (e.g., commands or data) therebetween via an inter-peripheral communication scheme (e.g., a bus, general-purpose input and output (GPIO), serial peripheral interface (SPI), or mobile industry processor interface (MIPI)).

According to an embodiment, commands or data may be transmitted or received between the electronic device 101 and the external electronic device (e.g., the electronic device 104) via the server 108 coupled with the second network 199. Each of the external electronic devices (e.g., the electronic device 102 or 104) may be a device of the same type as or a different type from the electronic device 101. All or some of operations to be executed by the electronic device 101 may be executed by one or more of the external electronic devices (e.g., the electronic devices 102 and 104 and the server 108). For example, if the electronic device 101 needs to perform a function or a service automatically, or in response to a request from a user or another device, the electronic device 101, instead of, or in addition to, executing the function or service, may request one or more external electronic devices to perform at least a part of the function or service. The one or more external electronic devices receiving the request may perform the at least part of the function or the service requested, or an additional function or an additional service related to the request and may transfer a result of the performance to the electronic device 101. The electronic device 101 may provide the result, with or without further processing of the result, as at least part of a response to the request. To that end, cloud computing, distributed computing, mobile edge computing (MEC), or client-server computing technology may be used, for example. The electronic device 101 may provide ultra-low latency services using, e.g., distributed computing or MEC. According to another embodiment, the external electronic device (e.g., the electronic device 104) may include an Internet-of-things (IoT) device. The server 108 may be an intelligent server using machine learning and/or a neural network. The external electronic device (e.g., the electronic device 104) or the server 108 may be included in the second network 199. The electronic device 101 may be applied to intelligent services (e.g., a smart home, a smart city, a smart car, or healthcare) based on 5G communication technology or IoT-related technology.

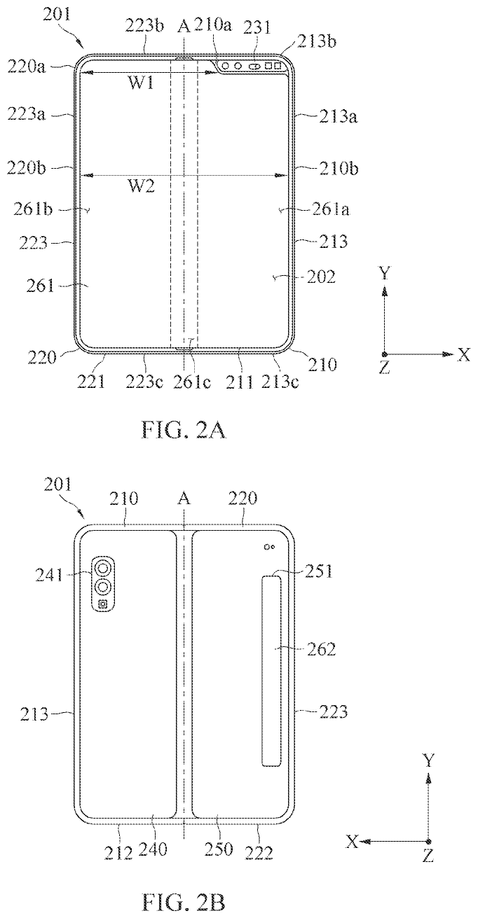

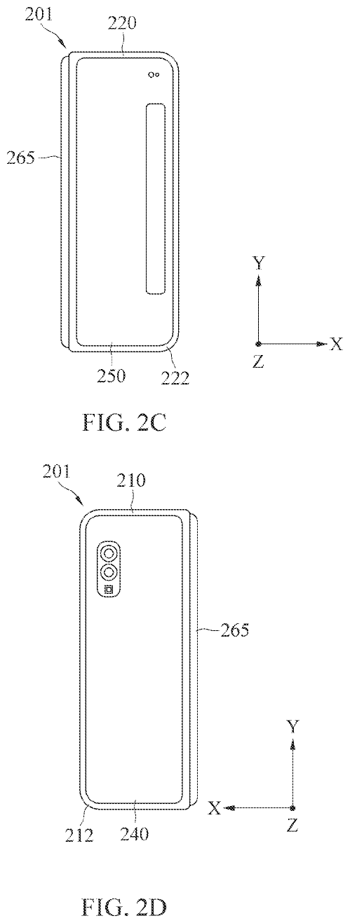

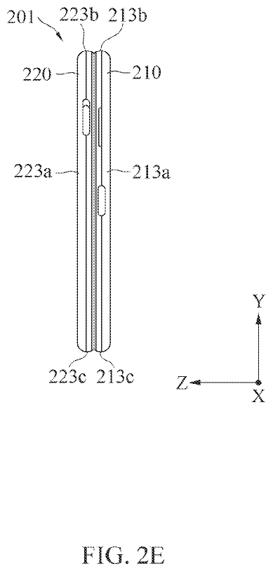

FIG. 2A is a plan view of an electronic device according to an embodiment, FIG. 2B is a rear view of an electronic device according to an embodiment, FIG. 2C is a plan view of an electronic device according to an embodiment, FIG. 2D is a rear view of an electronic device according to an embodiment, and FIG. 2E is a side view of an electronic device according to an embodiment.

Specifically, FIGS. 2A and 2B show an electronic device 201 in an unfolded state, and FIGS. 2C to 2E show the electronic device 201 in a folded state. According to various embodiments, the electronic device 201 may be folded in a folding direction or unfolded in an unfolding direction, and such an electronic device 201 may also be referred to as a “foldable device.” Although a foldable device will be described hereinafter as an example of the electronic device 201, the electronic device 201 is not limited to this example in actual implementations, and various examples may also be applicable.

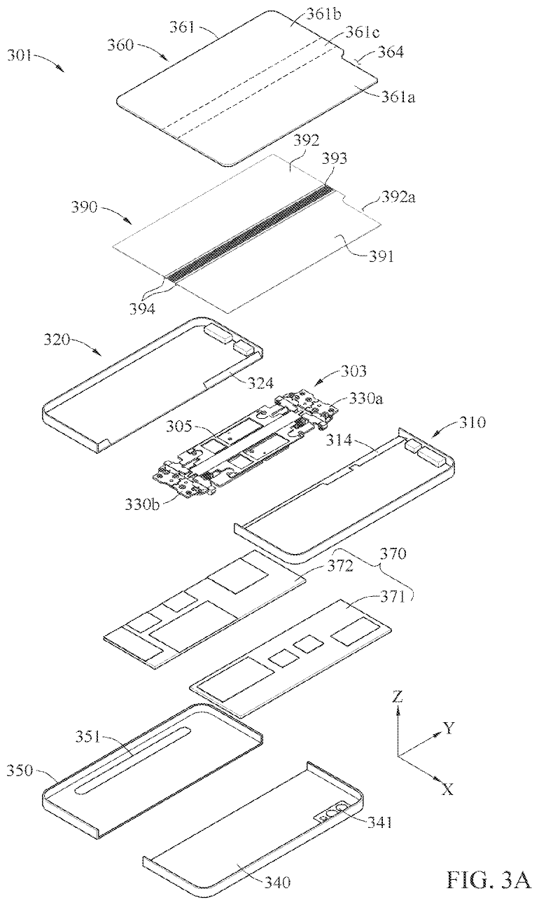

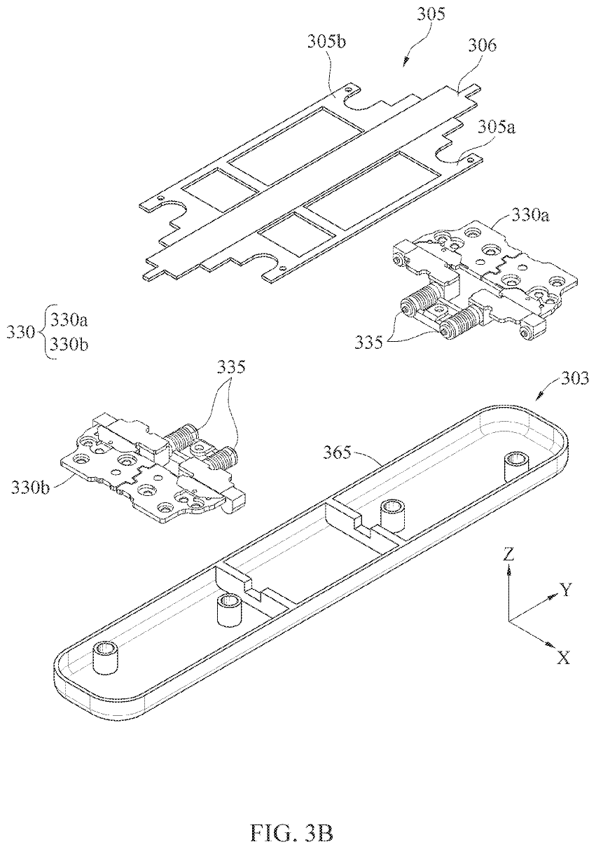

Referring to FIGS. 2A to 2E, according to an embodiment, the electronic device 201 may include a pair of housings 210 and 220 rotatably or movably coupled to each other through a hinge unit (e.g., a hinge unit 303 in FIG. 3A) so as to be folded against each other, a hinge cover 265 covering a foldable portion of the pair of housings 210 and 220, and a display 261 (e.g., a flexible display or foldable display) disposed in a space formed by the pair of housings 210 and 220. A surface on which the display 261 is disposed may be defined herein as the front of the electronic device 201, and a surface opposite to the front may be defined herein as the back or rear of the electronic device 201. In addition, a surface surrounding a space between the front and the back may be defined herein as the side of the electronic device 201.

In an embodiment, the pair of housings 210 and 220 may include a first housing 210 including a sensor area 231, a second housing 220, a first rear cover 240, and a second rear cover 250. The pair of housings 210 and 220 of the electronic device 201 is not limited to the shape or the combination and/or coupling of parts or components shown in FIGS. 2A to 2E but may be implemented by other shapes or other combinations and/or couplings of parts or components.

In an embodiment, the first housing 210 and the second housing 220 may disposed on both sides with respect to a folding axis A and may be arranged substantially symmetrically with respect to the folding axis A. In an embodiment, an angle or distance formed between the first housing 210 and the second housing 220 may depend on whether the electronic device 201 is in an unfolded state, a folded state, or an intermediate state. In an embodiment, unlike the second housing 220, the first housing 210 may include the sensor area 231 in which various sensor modules (e.g., the sensor module 176 in FIG. 1) are disposed, but in other portions excluding this, the first housing 210 and the second housing 220 may have a mutually symmetrical shape. In some embodiments, the sensor area 231 may be disposed in at least a portion of the second housing 220. In some embodiments, the sensor area 231 may be replaced with at least a portion of the second housing 220. The sensor area 231 may include, for example, a camera hole area, a sensor hole area, an under-display camera (UDC) area, and/or an under-display sensor (UDS) area. In an embodiment, the electronic device 201 may operate in an in-folding method and/or out-folding manner as the first housing 210 is rotated in a range between 0 degrees and 360 degrees with respect to the second housing 220 through the hinge unit 303. In an embodiment, the hinge unit 303 may be formed vertically when the electronic device 201 is viewed from above, or horizontally. In an embodiment, the hinge unit 303 may be provided as a plurality of hinge units 303. For example, the plurality of hinge units 303 may all be arranged in the same direction. For another example, some of the hinge units 303 among the plurality of hinge units 303 may be arranged in different directions to be folded.

In an embodiment, the first housing 210 may be connected to the hinge unit 303 when the electronic device 201 is in the unfolded state. The first housing 210 may include a first surface 211 disposed to face the front of the electronic device 201, a second surface 212 facing in an opposite direction of the first side 211, and a first side portion 213 surrounding at least a portion of a space between the first surface 211 and the second surface 212. The first side portion 213 may include a first side surface 213a disposed substantially parallel to the folding axis A, a second side surface 213b extending from one end of the first side surface 213a in a direction substantially perpendicular to the folding axis A, and a third side surface 213c extending from the other end of the first side surface 213a in a direction substantially perpendicular to the folding axis A and substantially parallel to the second side surface 213b. The second housing 220 may be connected to the hinge unit 303 when the electronic device 201 is in the unfolded state. The second housing 220 may include a third surface 221 disposed to face the front of the electronic device 201, a fourth surface 222 facing in an opposite direction of the third surface 221, and a second side portion 223 surrounding at least a portion of a space between the third surface 221 and the fourth surface 222. The second side portion 223 may include a fourth side surface 223a disposed substantially parallel to the folding axis A, a fifth side surface 223b extending from one end of the fourth side surface 223a in a direction substantially perpendicular to the folding axis A, and a sixth side surface 223c extending from the other end of the fourth side surface 223a in a direction substantially perpendicular to the folding axis A and substantially parallel to the fifth side surface 223b. The first surface 211 and the third surface 221 may face each other when the electronic device 201 is in the folded state.

In an embodiment, the electronic device 201 may include a recess-shaped receiving portion 202 that receives therein the display 261 through a structural coupling of the first housing 210 and the second housing 220. The receiving portion 202 may have substantially the same size as the display 261. In an embodiment, due to the sensor area 231, the receiving portion 202 may have two or more different widths in a direction perpendicular to the folding axis A. For example, the receiving portion 202 may have a first width W1 between a first portion 210a of the first housing 210 formed at an edge of the sensor area 231 and a second portion 220a of the second housing 220 parallel to the folding axis A, and a second width W2 between a third portion 210b of the first housing 210 that is parallel to the folding axis A without overlapping the sensor area 231 and a fourth portion 220b of the second housing 220. In this case, the second width W2 may be greater than the first width W1. That is, the receiving portion 202 may be formed to have the first width W1 from the first portion 210a of the first housing 210 to the second portion 220a of the second housing 220 and the second width W2 from the third portion 210b of the first housing 210 to the fourth portion 220b of the second housing 220, which have a mutually asymmetrical shape. The first portion 210a and the third portion 210b of the first housing 210 may be formed at different distances from the folding axis A. However, the width of the receiving portion 202 may not be limited to the illustrated example. For example, the receiving portion 202 may have three or more different widths depending on the shape of the sensor area 231 or the asymmetrical shape of the first housing 210 and the second housing 220.

In an embodiment, at least a portion of the first housing 210 and the second housing 220 may be formed of a metallic material or a non-metallic material having the rigidity suitable for supporting the display 261.

In an embodiment, the sensor area 231 may be formed to be adjacent to one corner of the first housing 210. However, the arrangement, shape, or size of the sensor area 231 may not be limited to the illustrated example. In some embodiments, the sensor area 231 may be formed at another corner of the first housing 210 or in any area between upper and lower corners. In some embodiments, the sensor area 231 may be disposed in at least a portion of the second housing 220. In some embodiments, the sensor area 231 may be formed in a shape extending between the first housing 210 and the second housing 220.

In an embodiment, the electronic device 201 may include at least one component for performing various functions, which is disposed to be exposed to the front of the electronic device 201 through the sensor area 231 or through at least one opening formed in the sensor area 231. The component may include, for example, at least one of a front camera module, a receiver, a proximity sensor, an illumination sensor, an iris recognition sensor, an ultrasonic sensor, or an indicator.

In an embodiment, the first rear cover 240 may be disposed on the second surface 212 of the first housing 210 and may have substantially rectangular edges. At least a portion of the edges of the first rear cover 240 may be surrounded by the first housing 210. The second rear cover 250 may be disposed on the fourth surface 222 of the second housing 220 and may have substantially rectangular edges. At least a portion of the edges of the second rear cover 250 may be surrounded by the second housing 220.

In an embodiment, the first rear cover 240 and the second rear cover 250 may have a substantially symmetrical shape with respect to the folding axis A. In another embodiment, the first rear cover 240 and the second rear cover 250 may have different shapes. In still another embodiment, the first housing 210 and the first rear cover 240 may be integrally formed, and the second housing 220 and the second rear cover 250 may be integrally formed.

In an embodiment, the first housing 210, the second housing 220, the first rear cover 240, and the second rear cover 250 may be coupled to each other to provide a space in which various components (e.g., a PCB, the antenna module 197 in FIG. 1, the sensor module 176 in FIG. 1, or the battery 189 in FIG. 1) of the electronic device 201 are to be disposed. In an embodiment, at least one component may be visually exposed on the rear of the electronic device 201. For example, at least one component may be visually exposed through the first rear area 241 of the first rear cover 240. In this case, the component may include a proximity sensor, a rear camera module, and/or a flash. In an embodiment, at least a portion of a sub-display 262 may be visually exposed through the second rear area 251 of the second rear cover 250. In an embodiment, the electronic device 201 may include a sound output module (e.g., the sound output module 155 in FIG. 1) disposed through at least a partial area of the second rear cover 250.

In an embodiment, the display 261 may be disposed in the receiving portion 202 formed by the pair of housings 210 and 220. For example, the display 261 may be disposed to occupy substantially most of the front of the electronic device 201. The front of the electronic device 201 may include an area in which the display 261 is disposed, and a partial area (e.g., an edge area) of the first housing 210 and a partial area (e.g., an edge area) of the second housing 220 that are adjacent to the display 261. The rear of the electronic device 201 may include the first rear cover 240, a partial area (e.g., an edge area) of the first housing 210 adjacent to the first rear cover 240, the second rear cover 250, and a partial area (e.g., an edge area) of the second housing 220 adjacent to the second rear cover 250.

In an embodiment, the display 261 may be a display in which at least a partial area may be deformed into a flat or curved surface. In an embodiment, the display 261 may include a folding area 261c, a first area 261a on a first side (e.g., a right side) with respect to the folding area 261c, and a second area 261b on a second side (e.g., a left side) with respect to the folding area 261c. The first area 261a may be disposed on the first surface 211 of the first housing 210, and the second area 261b may be disposed on the third surface 221 of the second housing 220. However, such an areal division of the display 261 is provided only as an example, the display 261 may be divided into a plurality of areas depending on the structure or function of the display 261.

For example, as shown in FIGS. 2A and 2B, the display 261 may be divided into areas by the folding area 261c or the folding axis A extending parallel to a Y axis, but the display 261 may be divided into areas by another folding area (e.g., a folding area extending parallel to an X axis) or another folding axis (e.g., a folding axis parallel to the X-axis). The areal division of the display 261 described above may only be a physical division by the pair of housings 210 and 220 and the hinge unit 303, and the display 261 may display a substantially one screen through the pair of housings 210 and 220 and the hinge unit 303.

In an embodiment, the first area 261a may include a notch area formed along the sensor area 231 but may have a substantially symmetrical shape with the second area 261b in other areas. In another embodiment, the first area 261a and the second area 261b may have a substantially symmetrical shape with respect to the folding area 261c.

In an embodiment, the hinge cover 265 may be disposed between the first housing 210 and the second housing 220 and configured to cover the hinge unit 303. The hinge cover 265 may be hidden or exposed to the outside by at least a portion of the first housing 210 and the second housing 220 depending on an operating state of the electronic device 201. For example, as shown in FIGS. 2A and 2B, when the electronic device 201 is in the unfolded state, the hinge cover 265 may be hidden by the first housing 210 and the second housing 220 not to be exposed to the outside. As shown in FIGS. 2C to 2E, when the electronic device 201 is in the folded state, the hinge cover 265 may be exposed to the outside between the first housing 210 and the second housing 220. In addition, when the electronic device 201 is in the intermediate state in which the first housing 210 and the second housing 220 form an angle with each other, at least a portion of the hinge cover 265 may be exposed to the outside between the first housing 210 and the second housing 220. In this case, an area of the hinge cover 265 exposed to the outside may be smaller than an area of the hinge cover 265 exposed to the outside when the electronic device 201 is in the folded state. In an embodiment, the hinge cover 265 may have a curved surface.

Regarding the operations of the electronic device 201, in an embodiment, when the electronic device 201 is in the unfolded state (e.g., a state of the electronic device 201 shown in FIGS. 2A and 2B), the first housing 210 and the second housing 220 may form a first angle (e.g., about 180 degrees) with each other, and the first area 261a and the second area 261b of the display 261 may be oriented substantially in the same direction. The folding area 261c of the display 261 may be substantially on the same plane as the first area 261a and the second area 261b.

In another embodiment, when the electronic device 201 is in the unfolded state, as the first housing 210 rotates or moves at a second angle (e.g., about 360 degrees) with respect to the second housing 220, the first housing 210 and the second housing 220 may be folded in opposite directions such that the second surface 212 and the fourth surface 222 face each other. In addition, when the electronic device 201 is in the folded state (e.g., a state of the electronic device 201 shown in FIGS. 2C to 2E), the first housing 210 and the second housing 220 may face each other. The first housing 210 and the second housing 220 may form an angle of about 0 degrees to about 10 degrees, and the first area 261a and the second area 261b of the display 261 may face each other.

In an embodiment, at least a portion of the folding area 261c of the display 261 may be deformed into a curved surface. In addition, when the electronic device 201 is in the intermediate state, the first housing 210 and the second housing 220 may form a specific angle with each other. The angle (e.g., a third angle, about 90 degrees) formed between the first area 261a and the second area 261b of the display 261 may be greater than an angle formed when the electronic device 201 is in the folded state and may be smaller than an angle formed when the electronic device 201 is in the unfolded state. At least a portion of the folding area 261c of the display 261 may be deformed into a curved surface. In this case, a curvature of the curved surface of the folding area 261c may be smaller than a curvature of the curved surface of the folding area 261c formed when the electronic device 201 is in the folded state.

Meanwhile, an embodiment of an electronic device described herein is not limited to the form factor of the electronic device 201 described above with reference to FIGS. 2A to 2E, and various form factors may also be applicable.

FIG. 3A is an exploded perspective view of an electronic device according to an embodiment, and FIG. 3B is an exploded perspective view of a hinge unit according to an embodiment.

Referring to FIGS. 3A and 3B, according to an embodiment, an electronic device 301 (e.g., the electronic device 101 in FIG. 1 and the electronic device 201 in FIGS. 2A to 2E) may include a display module 360 (e.g., the display module 160 in FIG. 1), a hinge unit 303, a substrate 370, a first housing 310 (e.g., the first housing 210 in FIG. 2A), a second housing 320 (e.g., the second housing 220 in FIG. 2A), a first rear cover 340 (e.g., the first rear cover 240 in FIG. 2B) including a first rear area 341 (e.g., the first rear area 241 in FIG. 2B), and a second rear cover 350 (e.g., the second rear cover 240 in FIG. 2B) including a second rear area 351 (e.g., the second rear area 251 in FIG. 2B).

In an embodiment, the display module 360 (e.g., the display 261 in FIG. 2A) may include a foldable display panel 361. The foldable display panel 361 may include a folding area 361c, a first area 361a on a first side (e.g., a right or −X direction) with respect to the folding area 361c, and a second area 361b on a second side (e.g., a left or +X direction) with respect to the folding area 361c. The foldable display panel 361 may include a notch area 364 formed in the first area 361a along a sensor area (e.g., the sensor area 231 in FIG. 2A), and the first area 364 excluding the notch area 364 may have a substantially symmetrical shape with the second area 361b.

In an embodiment, the first area 361a and the second area 361b may be unfolding areas that are distinguished from the folding area 361c, and may be rotated or moved in directions facing each other with respect to the folding area 361c. For example, as the folding area 361c is folded or unfolded in a folding direction (e.g., a +Z direction) or unfolding direction (e.g., a −Z direction), one surfaces (e.g., surfaces in the +Z direction) of the first area 361a and the second area 361b may move in directions facing each other or receding from each other. In an embodiment, the display module 360 may be supported by being seated on at least one layer or a foldable sheet 390, and may be folded or unfolded in conjunction with the foldable sheet 390 or the hinge unit 303.

In an embodiment, the foldable sheet 390 may be disposed between the display module 360 and the hinge unit 303. The foldable display panel 361 may be disposed on at least a portion of one surface (e.g., a top surface or a surface in the +Z direction) of the foldable sheet 390. The foldable sheet 390 may be formed in a shape corresponding to the foldable display panel 361. For example, a partial area 392a of the foldable sheet 390 may be formed in a shape corresponding to the notch area 364 of the foldable display panel 361.

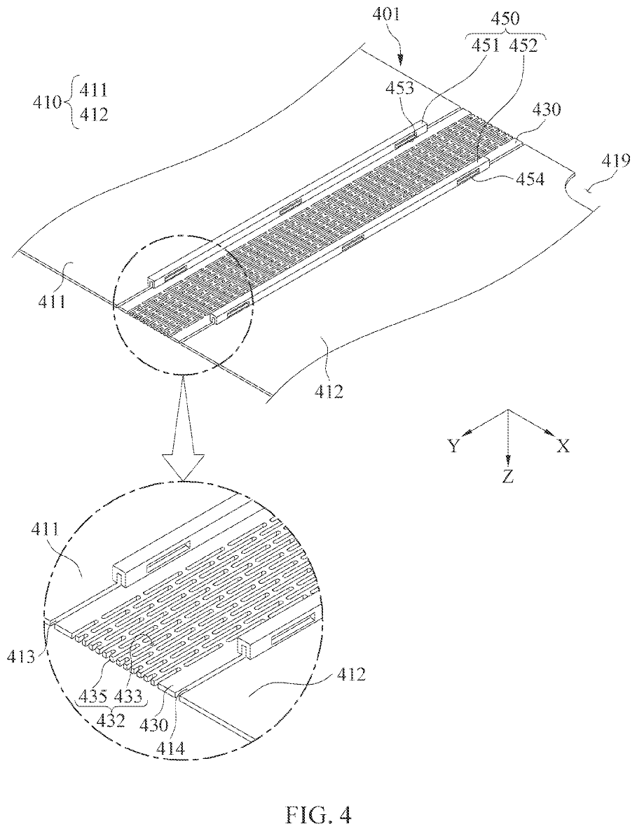

In an embodiment, the foldable sheet 390 may include a folding area 393, body areas 391 and 392 provided on a first side (e.g., the right or −X direction) and a second side (e.g., the left or +X direction) with respect to the folding area 393, and a bending area 394. The foldable sheet 390 will be described in detail below with reference to FIG. 4.

In an embodiment, the hinge unit 303 may include a hinge plate 305, a hinge assembly 330 disposed at both longitudinal ends of the hinge plate 305, and a hinge cover 365 that covers at least a portion of the hinge assembly 330 when the hinge assembly 330 is viewed from the outside. In an embodiment, the hinge unit 303 may be disposed between the foldable sheet 390 and the substrate 370.

In an embodiment, the hinge plate 305 may include a center plate 306 disposed horizontally to a folding axis (e.g., the folding axis A or the Y axis in FIG. 2A) of the hinge unit 303, and a first plate 305a and a second plate 305b that are disposed on both sides (e.g., a +/−Y direction) with respect to the center plate 306 to be rotated or moved. In an embodiment, the center plate 306 may be fixed to the hinge unit 303, and the first plate 305a and the second plate 305b may be rotated or moved by a gear 335 of the hinge unit 303 to fold other parts or components.

For example, the first plate 305a and the second plate 305b may each be coupled to one of the first housing 310 and the second housing 320, and the first plate 305a and the second plate 305b may rotate or move the first housing 310 and the second housing 320 while supporting them.

In an embodiment, the hinge assembly 330 may include a first hinge assembly 330a disposed on one side (e.g., the +Y direction) of the hinge plate 305 and a second hinge assembly 330b disposed on the other side (e.g., the −Y direction) of the hinge plate 305. In an embodiment, the first hinge assembly 330a and the second hinge assembly 330b may be arranged symmetrically with respect to an axis (e.g., an X-axis passing through the center of the hinge plate 305) that is perpendicular to the folding axis A and crosses the center of the hinge plate 305. The first hinge assembly 330a and the second hinge assembly 330b may each include a plurality of gears 335.

In an embodiment, the plurality of gears 335 may be arranged to be symmetrical with respect to the folding axis A. The plurality of gears 335 may be inserted into a gear shaft (not shown) to be rotated thereabout and may rotate the first plate 305a and the second plate 305b around the center plate 306.

In an embodiment, the substrate 370 may include a first substrate 371 and a second substrate. The first substrate 371 and the second substrate 372 may be disposed inside a space formed by the hinge unit 303, the first housing 310, the second housing 320, the first rear cover 340, and the second rear cover 350. On the first substrate 371 and the second substrate 372, parts or components for implementing various functions of the electronic device 301 may be mounted.

In an embodiment, the first rear cover 340 may include the first rear area 341, and the second rear cover 350 may include the second rear area 351. In this case, various parts or components including the first substrate 371 may be disposed or coupled in the first rear area 341, and various parts or components including the second substrate 372 may be disposed or coupled in the second rear area 351. The first rear cover 340 and the second rear cover 350 may be respectively connected to the first housing 310 and the second housing 320 and may be rotatably connected to the hinge unit 303.

In an embodiment, the first housing 310 and the second housing 320 may be assembled with each other to be coupled to both sides of the hinge unit 303 with the display module 360 coupled to the hinge unit 303. The first housing 310 and the second housing 320 may be coupled to the hinge unit 303 by sliding on both sides of the hinge unit 303.

In an embodiment, the first housing 310 may include a first rotational support surface 314, and the second housing 320 may include a second rotational support surface 324 corresponding to the first rotational support surface 314. The first rotational support surface 314 and the second rotational support surface 324 may each include a curved surface corresponding to a curved surface included in the hinge cover 365 (e.g., the hinge cover 265 in FIG. 2C).

In an embodiment, when the electronic device 301 is in an unfolded state (e.g., the electronic device 201 in FIGS. 2A and 2B), the first rotational support surface 314 and the second rotational support surface 324 may cover the hinge cover 365, and thus the hinge cover 365 may not be exposed to the rear of the electronic device 301 or may be minimally exposed. In addition, when the electronic device 301 is in a folded state (e.g., the electronic device 201 in FIGS. 2C to 2E), the first rotational support surface 314 and the second rotational support surface 324 may be rotated along the curved surface included in the hinge cover 365, and thus the hinge cover 365 may be maximally exposed to the rear of the electronic device 301.

FIG. 4 is a perspective view of a foldable sheet 401 according to an embodiment.

Referring to FIG. 4, according to an embodiment, the foldable sheet 401 (e.g., the foldable sheet 390 in FIG. 3) may include a body area 410 (e.g., the body areas 391 and 392 in FIG. 3A), a folding area 430 (e.g., the folding area 393 in FIG. 3A), and a bending area 450 (e.g., the bending area 394 in FIG. 3A).

In an embodiment, the foldable sheet 401 may be connected to one surface of a foldable display panel (e.g., the foldable display panel 361 in FIG. 3A) to provide flexibility to the foldable display panel 361 and strengthen the rigidity of an electronic device (e.g., the electronic device 301 in FIG. 3A). In an embodiment, the foldable sheet 401 may be a “metal sheet” or a “lattice sheet,” and may be a “main metal sheet” that is distinguished from a sub-metal sheet 470 (e.g., a sub-metal sheet 470 of FIG. 9).

In an embodiment, the foldable sheet 401 may include the folding area 430, and a first body 411 disposed on a first side (e.g., a right or −X direction) and a second body 412 disposed on a second side (e.g., a left or +X direction) with respect to the folding area 430. The foldable sheet 401 may be connected or coupled to one surface of the foldable display panel 361 such that the first body 411, the second body 412, and the folding area 430 of the foldable sheet 401 are disposed in areas respectively corresponding to a first area (e.g., the first area 361a in FIG. 3A), a second area (e.g., the second area 361b in FIG. 3A), and the folding area 430 (e.g., the folding area 361c in FIG. 3A) of the foldable display panel 361.

In an embodiment, the thickness of the foldable sheet 401 may be approximately 200 micrometers in a case where the electronic device 301 including the foldable sheet 401 is a small electronic device such as a smartphone, and the thickness of the foldable sheet 401 may be approximately 400 micrometers in a case where the electronic device 301 is a relatively large electronic device such as a tablet personal computer (PC) and a laptop.

In an embodiment, the body area 410 may include the first body 411 and the second body 412 disposed to be spaced apart from the first body 411 in one direction (e.g., an X-axis direction). The body area 410 may be an unfolding area distinguished from the folding area 430. As the folding area 430 is folded or unfolded in a folding direction (e.g., a +Z direction) or in an unfolding direction (e.g., a −Z direction), the body area 410 may move or rotate in a direction in which the first body 411 and the second body 412 approach closer to each other or recede from each other with respect to the folding area 430. For example, a top surface of the first body 411 in an upward direction (e.g., the −Z direction) and a top surface of the second body 412 in the upward direction (e.g., the −Z direction) may be disposed to substantially face each other in a folded state, and may be disposed substantially parallel to each other on the same plane (e.g., an X-Y plane) in an unfolded state.

In an embodiment, the folding area 430 may be disposed between the first body 411 and the second body 412 and may be folded in a first direction (e.g., the folding direction or +Z-axis direction) such that the first body 411 and the second body 412 face each other. The folding area 430 may include a lattice area 432.

In an embodiment, the lattice area 432 may include a plurality of lattice holes 433 and a plurality of bridges 435. The plurality of lattice holes 433 may be arranged to be in a matrix form in which rows and columns are aligned in a direction (e.g., the X-axis direction) in which the first body 411 and the second body 412 are spaced apart and in a direction (e.g., the Y-axis direction) perpendicular to the folding direction. The plurality of lattice holes 433 may have an elliptical or polygonal structure with a major axis extending in the direction (e.g., the Y-axis direction) perpendicular to the folding direction. The plurality of bridges 435 may be disposed between the plurality of lattice holes 433 to connect the folding area 430 into a single body.

In an embodiment, the lattice area 432 may increase the flexibility of the foldable sheet 401 in a direction (e.g., the +/-Z direction) perpendicular to the folding area 430. In an embodiment, the lattice area 432 may contribute to smoothly performing a folding operation of the foldable sheet 401 and strengthening the rigidity.

In an embodiment, the bending area 450 may connect the body area 410 and the folding area 430. The bending area 450 may include a first bending area 451 that connects one end (e.g., an end in the +X direction) of the folding area 430 and the first body 411 and a second bending area 452 that connects the other end (e.g., an end in the −X direction) of the folding area 430 and the second body 412.

In an embodiment, the bending area 450 may have a structure that is bent at least twice to protrude in a second direction (e.g., the unfolding direction or −Z direction) opposite to the first direction (e.g., the folding direction or +Z direction) such that the first body 411 and the second body 412 are arranged in parallel to each other when the folding area 430 is in an unfolded state. For example, the first bending area 451 can extend vertically from the first body 411 and the folding area 430, and the second bending area 452 can extend vertically from the second body 412 and the folding area 430. In an embodiment, the bending area 450 may be bent multiple times to have a “⊏”-shaped (or “n”-shaped) cross section in an X-Z direction. For example, the first bending area 451 may be bent at least twice or more such that the first body 411 and the folding area 430 are arranged in parallel on the same plane (e.g., the X-Y plane), by being bent, from a connecting point with the first body 411, firstly in the upward direction (e.g., the −Z direction), secondly in a horizontal direction (e.g., the +X direction), thirdly in a downward direction (e.g., the +Z direction), and fourthly in the horizontal direction (e.g., the +X direction).

For example, the second bending area 452 may be bent at least twice or more such that the second body 412 and the folding area 430 are arranged in parallel on the same plane (e.g., the X-Y plane), by being bent, from a connecting point with the second body 412, firstly in the upward direction (e.g., the −Z direction), secondly in a horizontal direction (e.g., the −X direction), thirdly in the downward direction (e.g., the +Z direction), and fourthly in the horizontal direction (e.g., the −X direction). However, in actual implementation, examples are not limited thereto, and the bending area 450 may be bent multiple times to have a “V”-shaped or “U”-shaped cross section in the X-Z direction or have various cross-sectional shapes.

In an embodiment, the bending area 450 may be bent at least twice to form a first gap 413 and a second gap 414, which are gaps spaced apart between the body area 410 and the folding area 430. For example, the first gap 413 may be provided between the first body 411 and the folding area 430, and the second gap 414 may be provided between the second body 412 and the folding area 430.

In an embodiment, the first gap 413 and the second gap 414 may be provided between the folding area 430 and the body area 410 to allow the cross section of the foldable sheet 401 in a plane direction (e.g., the X-Y plane) to have a structure in which the folding area 430 and the body area 410 are spaced apart in substantially all areas, and these gaps may be the first gap 413 and the second gap 414.

In an embodiment, when the foldable sheet 401 enters the folded state, a lower surface in the folding direction (e.g., the +Z direction) may be contracted and an upper surface in the unfolding direction (e.g., the −Z direction) may be extended, with respect to the center of the body area 410 and the folding area 430. The bending area 450 may form the first gap 413 and the second gap 414 to provide an extended space of the foldable sheet 401, which may minimize a deformation occurring by the extension and contraction of the upper surface and the lower surface of the foldable sheet 401 in the folded state.

In an embodiment, the bending area 450 may be bent at least twice to form the first gap 413 and the second gap 414, and the first gap 413 and the second gap 414 may prevent or suppress, as the foldable sheet 401 repeats folding and unfolding operations, some portion from being extended and protruding, and prevent or suppress a crease that may be generated between the folding area 430 and the body area 410. In an embodiment, since the foldable sheet 401 is likely to have a crease formed near a lattice area, the bending area 450 may intensively prevent or suppress a corresponding area from being bent or curved.

In an embodiment, the foldable sheet 401 including the bending area 450 may not require a separate attachment to compensate for such a crease, and a fixing attachment, in particular, may be denatured according to a temperature change and may not be desirable for semi-permanent use. However, in an embodiment, the foldable sheet 401 may semi-permanently suppress the crease using the bending area 450. In addition, the bending area 450 may be formed in an area where a crease is likely to occur to distribute a force of some areas of the folding area 430 receiving an external force from a hinge or a user into a development direction (e.g., the Y-axis direction) of the bending area 450, thereby effectively preventing the crease.

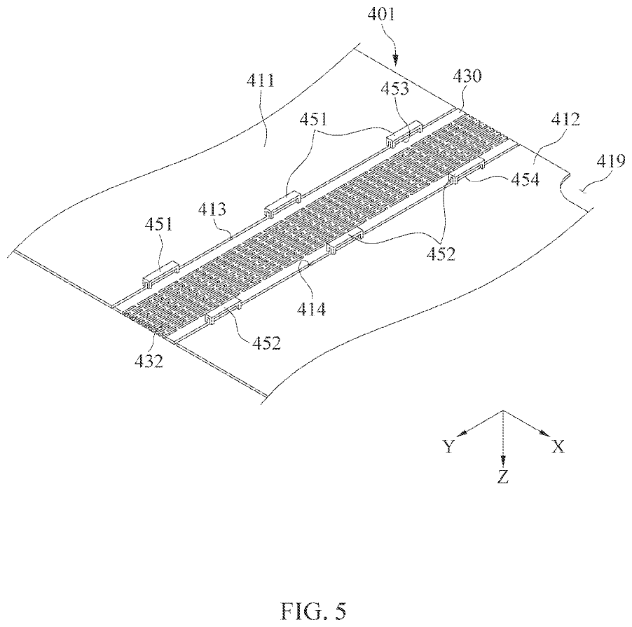

In an embodiment, the second body 412 may include a notch area 419, and the bending area 450 may include a first bending hole 453 and a second bending hole 454. The first and second bending holes 453 are configured to support a cover and are described in greater detail below with reference to FIG. 5.

In an embodiment, the body area 410, the folding area 430, and the bending area 450 may be formed as a single body in which they are continuous with each other. For example, the body area 410, the folding area 430, and the bending area 450 may include at least some of a metallic material, a polymeric compound, or a carbon fiber-reinforced plastic (CFRP). In an embodiment, the body area 410 may be formed of a rigid material to support the foldable display panel 361 and prevent a screen from being turned off, and the bending area 450 and the folding area 430 may be formed of a flexible material to be folded and unfolded with the shape that is bent at least twice and folded being maintained.

In an embodiment, the body area 410, the folding area 430, and the bending area 450 may be formed through injection molding of a single metal sheet. For example, an injection device (not shown) may include a core (not shown) having a structure of the foldable sheet 401 shown in FIG. 4 to perform injection molding. Alternatively, the injection device (not shown) may form the foldable sheet 401 by perforating the foldable sheet 401 that is substantially flat to form the plurality of lattice holes 433 and the first gap 413 and the second gap 414 and bending the bending area 450. In an embodiment, the order and method of performing such a perforating process and a bending process for the foldable sheet 401 are not limited to the foregoing but may be implemented in various ways.

FIG. 5 is a perspective view of the foldable sheet 401 according to an embodiment.

Referring to FIG. 5, according to an embodiment, the foldable sheet 401 may include a plurality of first bending areas 451 and a plurality of second bending areas 452.

In an embodiment, the bending area 450 may include the plurality of first bending areas 451 and the plurality of second bending areas 452 in a direction (e.g., a Y-axis direction) surrounding the folding area 430. In an embodiment, at least some of the plurality of first bending areas 451 may include a first bending holes 453, and at least some of the plurality of second bending areas 452 may include a second bending hole 454. In an embodiment, the plurality of first bending areas 451 and the plurality of second bending areas 452 may be formed by being bent at least twice and form a first gap 413 and a second gap 414, which are spaces between the body area 410 and the folding area 430.

In an embodiment, the plurality of first bending areas 451 and the plurality of second bending areas 452 may be aligned in a line or spaced apart from each other. Compared to the other embodiment including the single first bending area 451 shown in FIG. 4, the embodiment including the plurality of first bending areas 451 may facilitate the adjustment of a width (e.g., a length in an X-axis direction) of the first gap 413 which is a space between the first body 411 and the folding area 430, and may improve the convenience in coupling the foldable sheet 401. Likewise, the embodiment including the plurality of second bending areas 452 may also facilitate the adjustment of a width of the second gap 414.

Specifically, to attach the foldable sheet 401 to a foldable display panel 361 (e.g., the foldable display panel 361 in FIG. 3A), the folding area 430 of the foldable sheet 401 and the folding area 430 (e.g., the folding area 361c in FIG. 3A) of the foldable display panel 361 may initially be coupled to face each other, and the body area 410 of the foldable sheet 401 and a first area (e.g., the first area 361a in FIG. 3A) and a second area (e.g., the second area 361b in FIG. 3A) of the foldable display panel 361 may then be coupled to face each other. Additionally, a notch area (e.g., the notch area 364 in FIG. 3A) or a camera punch hole (not shown) of the foldable display panel 361 and the notch area 419 or the camera punch hole (not shown) of the foldable sheet 401 may be coupled to face each other accurately.

In an embodiment, compared to the foldable sheet 401 including the single first bending area 451 and the single second bending area 452, the foldable sheet 401 including the plurality of first bending areas 451 and the plurality of second bending areas 452 may have a smaller size of each bending area 450 and may be relatively effective in terms of deformation in shape. In an embodiment, the foldable sheet 401, which is more effective in the shape deformation, may facilitate the adjustment of a width of the first gap 413 and the second gap 414 between the body area 410 and the folding area 430, and may thus allow another part or component to be coupled by adjusting the first gap 413 and the second gap 414 in one direction (e.g., the Y-axis direction) after coupling the folding area 430 and at least one of the first body 411 and the second body 412, thereby providing the flexibility in response to the deformation of the foldable sheet 401 and the coupling convenience.

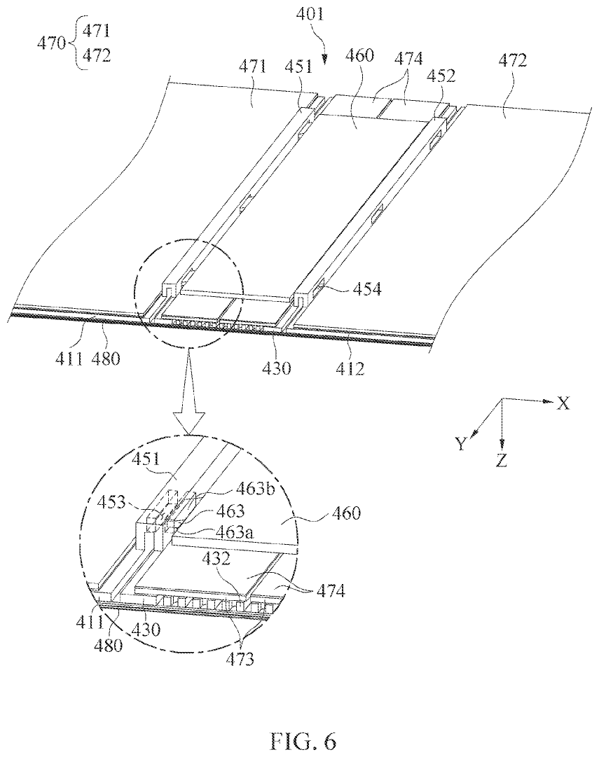

FIG. 6 is a perspective view of the foldable sheet 401 according to an embodiment.

Referring to FIG. 6, the foldable sheet 401 may include a sub-metal sheet 470 and a center cover 460.

In an embodiment, a foldable display panel 480 (e.g., the foldable display panel 361 in FIG. 3A) may be connected to a surface on a lower side (e.g., a +Z direction) of the foldable sheet 401, and the sub-metal sheet 470 may be connected to a surface on an upper side (e.g., a −Z direction) thereof. The sub-metal sheet 470 may include a first metal sheet 471 connected to the first body 411 and a second metal sheet 472 connected to the second body 412, and the first metal sheet 471 and the second metal sheet 472 may be disposed to be spaced apart from each other with a gap formed therebetween. To one surface on the upper or lower side of the foldable sheet 401, a bonding layer (e.g., a first bonding layer P1 and a second bonding layer P2 in FIG. 9) may be attached.

In an embodiment, a third metal sheet 473 and a connecting sheet 474 may be stacked on the upper side (e.g., the −Z direction) of the folding area 430 of the foldable sheet 401. The third metal sheet 473 and the connecting sheet 474 may each be divided in both directions (e.g., +/−X direction) based on the center of the bending area 450 and, as the foldable sheet 401 is folded, may move accordingly in both the divided directions.

In an embodiment, the sub-metal sheet 470 and the third metal sheet 473 may strengthen the rigidity of the foldable sheet 401 and improve the touch feel of the foldable display panel 480. The connecting sheet 474 may connect the third metal sheet 473 and the center cover 460, and may be formed of an elastic material to cushion a pressure that the folding area 430 presses the center cover 460 as the foldable sheet 401 is folded or to prevent a friction between the third metal sheet 473 and the center cover 460.

In an embodiment, the first bending area 451 may include a first bending hole 453 formed by penetrating in a direction (e.g., the +X direction) from the folding area 430 to the first body 411, and the second bending area 452 may include a second bending hole 454 formed by penetrating in a direction (e.g., the −X direction) from the folding area 430 to the second body 412. In an embodiment, the first bending hole 453 may be formed in an area of the first bending area 451 that protrudes in a vertical direction (e.g., the −Z direction) and may be formed by penetrating from the first body 411 to the bending area 450. In addition, the second bending hole 454 may be formed in an area of the second bending area 452 that protrudes in the vertical direction (e.g., the −Z direction) and may be formed by penetrating from the second body 412 to the bending area 450.

In an embodiment, the center cover 460 may disposed over the folding area 430 and cover the connecting sheets 474. For example, the center cover 460 may be disposed on one side of the folding area 430 in a second direction (e.g., the +Z direction) that is opposite to the first direction (e.g., the −Z direction) which is the folding direction, and may include a plurality of fasteners 463 inserted into the first bending hole 453 and the second bending hole 454 when the folding area 430 is in an unfolded state.

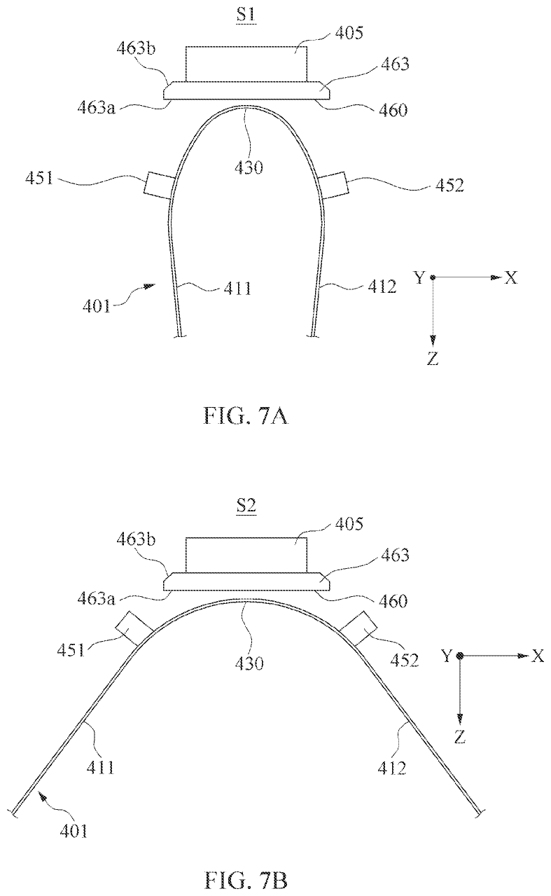

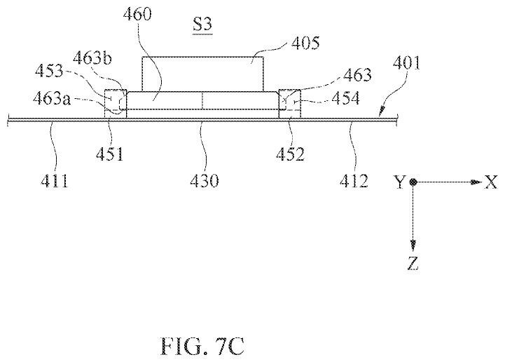

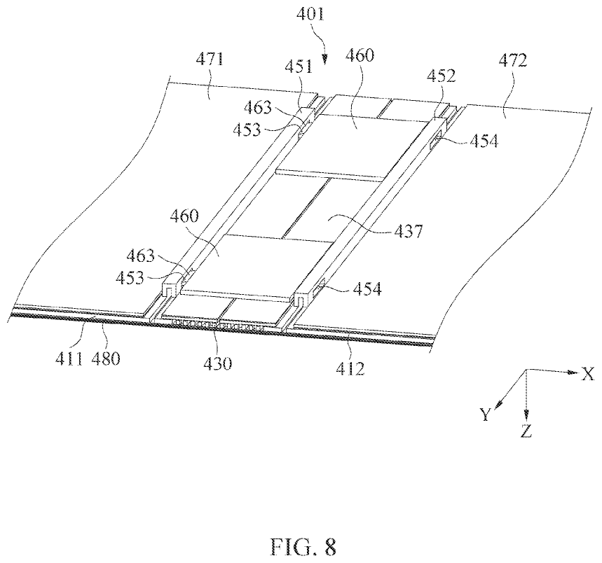

In an embodiment, the center cover 460 may be formed of a material that has a greater rigidity than the folding area 430 of the foldable sheet 401. The center cover 460 may be relatively less deformed compared to the foldable sheet 401, and may press the folding area 430 of the foldable sheet 401 to prevent or suppress the folding area 430 or the bending area 450 from rising and a crease from being formed. In an embodiment, the center cover 460 including the plurality of fasteners 463 will be described in greater detail with reference to FIGS. 7A to 7C.

FIG. 7A is a diagram illustrating one of folding states of the foldable sheet 401 according to an embodiment, FIG. 7B is a diagram illustrating one of folding states of the foldable sheet 401 according to an embodiment, and FIG. 7C is a diagram illustrating one of folding states of the foldable sheet 401 according to an embodiment.

Specifically, FIG. 7A shows a folded state S1 in which the foldable sheet 401 is folded, FIG. 7B shows an intermediate state S2 between the folded state S1 and an unfolded state S3 of the foldable sheet 401, and FIG. 7C shows the unfolded state S3 in which the foldable sheet 401 is unfolded.

Referring to FIGS. 7A to 7C, according to an embodiment, the foldable sheet 401 may be pressed by the center cover 460, which may suppress a crease from being formed.

In an embodiment, the foldable sheet 401 may be folded in a folding direction (e.g., a +Z direction) such that respective surfaces of the first body 411 and the second body 412 in one direction (e.g., the +Z direction) face each other with respect to the folding area 430, and the foldable sheet 401 may be unfolded in an unfolding direction (e.g., a −Z direction) such that respective surfaces of the first body 411 and the second body 412 in one direction (e.g., the −Z direction) recede from each other with respect to the folding area 430.

In an embodiment, the center cover 460 may be coupled to or supported by an external support 405 such as a hinge unit 303 (e.g., the hinge unit 303 in FIG. 3B), or the center cover 460 may be implemented as a center plate (e.g., the center plate 306 in FIG. 3B) of the hinge unit 303 to be coupled to and separated from the foldable sheet 401. For example, the center cover 460 may maintain its shape without being substantially folded when compared to the foldable sheet 401, and a fastener 463 of the center cover 460 may be inserted into the first bending hole 453 or the second bending hole 454 based on a deformation of the foldable sheet 401.

Specifically, regarding the states of the foldable sheet 401 according to an embodiment, when the foldable sheet 401 is in the unfolded state S3, the first body 411 and the second body 412 may form a preset unfolding angle (e.g., about 180 degrees), and the folding area 430 may be substantially the same plane (e.g., an X-Y plane) as the first body 411 and the second body 412.

In an embodiment, when the foldable sheet 401 is in the intermediate state S2, the first body 411 and the second body 412 may rotate or move based on the folding area 430, and respective surfaces of the first body 411 and the second body 412 in the folding direction (e.g., the +Z direction) may be folded in opposite directions to form a specific angle.

In an embodiment, when the foldable sheet 401 is in the folded state S1, the first body 411 and the second body 412 may face each other. The first body 411 and the second body 412 may form an angle of 0 degrees, which is substantially parallel, to 10 degrees, and at least a portion of the folding area 430 may be deformed into a curved surface.

In another embodiment, when the foldable sheet 401 is in the intermediate state S2, an angle formed by the first body 411 and the second body 412 may be greater than the angle formed in the folded state S1 of the foldable sheet 401 and may be smaller than the angle formed in the unfolded state S3 of the foldable sheet 401, and may be, for example, in a specific angle range between 10 degrees and 170 degrees, or about 90 degrees. In this case, at least a portion of the folding area 430 may be deformed into a curved surface, and a curvature of this curved surface of the folding area 430 may be smaller than a curvature of the curved surface of the folding area 430 formed when the foldable sheet 401 is in the folded state S1.

In an embodiment, when the foldable sheet 401 is in the folded state S1 or the intermediate state S2, the plurality of fasteners 463 may be separated from the first bending hole 453 and the second bending hole 454. In addition, when the foldable sheet 401 is in the unfolded state S3 or enters the unfolded state S3 from the intermediate state S2, the plurality of fasteners 463 may be inserted into the first bending hole 453 and the second bending hole 454. For example, when an unfolding angle of the foldable sheet 401 is 150 degrees or greater, a fastener 463 may be inserted into the first bending hole 453 and the second bending hole 454, and an insertion angle may vary depending on the shape of the bending area 450.

In an embodiment, the center cover 460 may include the plurality of fasteners 463 that protrude in a direction (e.g., the +/−X direction) from the folding area 430 of the foldable sheet 401 to the bending area 450, and the first bending hole 453 and the second bending hole 454 may move or rotate based on the plurality of fasteners 463 to be coupled to and separated from the plurality of fasteners 463.

In an embodiment, the center cover 460 may be formed of a material with greater rigidity than the foldable sheet 401 and may be substantially separated from the folding of the foldable sheet 401 to be fixed to the external support 405 such as the hinge unit 303. As the foldable sheet 401 is deformed from the folded state S1 to the unfolded state S3, the plurality of fasteners 463 may be inserted into the first bending hole 453 and the second bending hole 454, and the bending area 450 may thus be pressed. For example, in the unfolded state S3, a lower surface of the plurality of fasteners 463 may press a lower surface of the first bending hole 453 or the second bending hole 454, which may prevent or suppress the bending area 450 from rising.

In an embodiment, the center cover 460 may be formed of incompressible rubber or polymeric compound, and the foldable sheet 401 may be formed of a metallic material, which may prevent friction noise that may occur between the foldable sheet 401 and the center cover 460 in a coupling operation of a fastener 463.

In an embodiment, a fastener 463 may include a lower surface 463a that contacts the bending area 450 when the folding area 430 is in the unfolded state, and an upper surface 463b that is opposite to the lower surface 463a, and each of the plurality of fasteners 463 may be provided in a shape whose cross-sectional area decreases while developing in a direction from the center of the center cover 460 to the bending area 450.

For example, the lower surface 463a of the fastener 463 may be substantially a flat surface, and the upper surface 463b of the fastener 463 may be inclined downward by a preset angle while developing in a direction (e.g., the +/−X direction) from the center of the center cover 460 to the bending area 450 and, in this case, a cross-sectional area in a direction (e.g., a Y-Z direction) perpendicular to the direction in which the fastener 463 develops may decrease gradually. In an operation in which the foldable sheet 401 is deformed from the intermediate state S2 into the unfolded state S3, the first bending area 451 or the second bending area 452 may rise to escape from the fastener 463, and thus the shape with the cross-sectional area decreasing may allow the fastener 460 to be more stably inserted into and fixed to the first bending hole 453 or the second bending hole 454.

In an embodiment, the foldable sheet 401 including the center cover 460 may use the first gap 413 and the second gap 414 formed by the bending area 450 as described above to prevent a crease from being generated, and may use the center cover 460 to prevent or suppress the foldable sheet 401 from rising and suppress the crease.

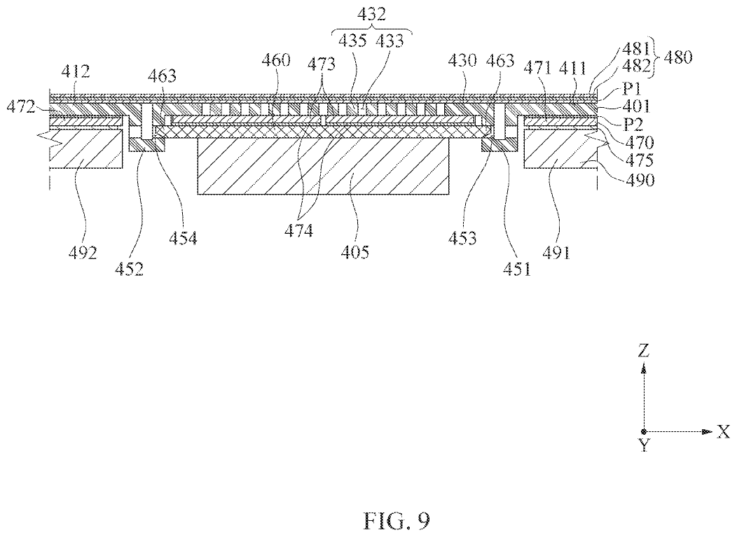

FIG. 8 is a perspective view of the foldable sheet 401 according to an embodiment.

Referring to FIG. 8, according to an embodiment, the foldable sheet 401 may include a plurality of center covers 460. In describing the embodiment with reference to FIG. 8, what has already been described about the foldable sheet 401 with reference to FIG. 6 will be omitted.

In an embodiment, the plurality of center covers 460 may be arranged in the folding area 430 of the foldable sheet 401 to be spaced apart from each other in a direction (e.g., a Y-axis direction) perpendicular to a direction (e.g., an X-axis direction) in which the first body 411 and the second body 412 are spaced apparat from each other. Each of the plurality of center covers 460 may include a plurality of fasteners 463, and the first bending area 451 and the second bending area 452 may include a first bending hole 453 and a second bending hole 454 such that they are inserted into the plurality of fasteners 463 in an unfolded state.

In an embodiment, a center space 437 may be formed between the plurality of center covers 460. Although not shown in the drawing, a hinge unit 303 (e.g., the hinge unit 303 in FIG. 3B) may be disposed in the center space 437.

Specifically, a center plate (e.g., the center plate 306 in FIG. 3B) of the hinge unit 303 may be disposed. In an embodiment, the center plate 306 may be disposed in the center space 437, and the center plate 306 and the center cover 460 may be fixed and coupled to gears (e.g., the plurality of gears 335 in FIG. 3B) or internal parts or components of the hinge unit 303. In another embodiment, the center plate 306 may be implemented as the center covers 460 and may be fixed to the gears 335 of the hinge unit 303, and the first plate 305a and the second plate 305b that may rotate or move to both sides may be connected to the first body 411 and the second body 412, respectively.

In an embodiment, a first plate (e.g., the first plate 305a in FIG. 3B) and a second plate (e.g., the second plate 305b in FIG. 3B) disposed on both sides of the center plate 306 may be connected to a first sub-metal sheet 470 and a second sub-metal sheet 470, respectively. The hinge unit 303 may fold or unfold the foldable sheet 401 and the foldable display panel 480 by rotating the first plate 305a and the second plate 305b.

FIG. 9 is a cross-sectional view of the electronic device 301 according to an embodiment.

Referring to FIG. 9, the electronic device 301 may include an external support 405 and a pair of housings 490. In describing the embodiment with reference to FIG. 9, what has already been described about the foldable sheet 401 will be omitted.

In an embodiment, the external support 405 of the foldable sheet 401 may be a hinge unit (e.g., the hinge unit 303 in FIG. 3B) or a part or component of the hinge unit 303. The hinge unit 303 may be driven to be folded in a folding direction (e.g., a +Z direction) and unfolded in an unfolding direction (e.g., a −Z direction). The pair of housings 490 may include a first housing 491 connected to the first body 411 and a second housing 492 connected to the second body 412, and the first housing 491 and the second housing 492 may be coupled to the hinge unit 303 so as to be folded in opposite directions (e.g., the +Z direction) with respect to the hinge unit 303 to rotate or move in conjunction with the hinge unit 303.

In an embodiment, the center cover 460 may be fixed to a plurality of gears (e.g., the plurality of gears 335 in FIG. 3B) of the hinge unit 303. In this case, the external support 405 may be the plurality of gears 335 which is a part or component of the hinge unit 303. Specifically, referring to FIG. 3B, the hinge unit 303 of the electronic device 301 may include a pair of plates (e.g., the first plate 305a and the second plate 305b in FIG. 3B) respectively connected to the pair of housings 490 and spaced apart from each other, and the plurality of gears 335 disposed between the pair of plates 305a and 305b and rotating the pair of plates 305a and 305b in the folding direction. In this case, in an embodiment, the center cover 460 may be disposed between the plurality of gears 335 and the foldable sheet 401, and may be fixedly coupled to the gears 335 or the hinge cover 365.

In an embodiment, the pair of plates 305a and 305b of the electronic device 301 may be connected to the first housing 491 and the second housing 492, and the center cover 460 may be fixed to the hinge unit 303. While the center cover 460 is fixed, the hinge unit 303 may rotate the first housing 491 and the second housing 492 to fold or unfold the foldable sheet 401 and the foldable display panel 480.

In an embodiment, the center cover 460 may be disposed between the folding area 430 of the foldable sheet 401 and the hinge unit 303, and the third metal sheet 473 and the connecting sheet 474 may be disposed between the center cover 460 and the folding area 430. In an embodiment, the third metal sheet 473 and the connecting sheet 474 may be fixed to the center cover 460 and may be spaced apart from the foldable sheet 401 by a folding operation of the foldable sheet 401. In another embodiment, the third metal sheet 473 and the connecting sheet 474 may be fixed to the foldable sheet 401 and may be spaced apart from the center cover 460 by the folding operation of the foldable sheet 401.

In an embodiment, the foldable display panel 480 may include a light-emitting layer 482 on which a light-emitting device (not shown) or a light source (not shown) is disposed, and a glass layer 481 that protects the light-emitting layer 482 and transmits light. A first bonding layer P1 may be disposed between the foldable display panel 480 and the foldable sheet 401 to bond them.

In an embodiment, a second bonding layer P2 may be disposed between the foldable sheet 401 and the sub-metal sheet 470 to bond them, and a waterproof layer 475 may be disposed between the sub-metal sheet 470 and the pair of housings 490 to prevent water or liquid flowing into the electronic device 301 through the glass layer 481 or other areas from penetrating into the electronic device 301.

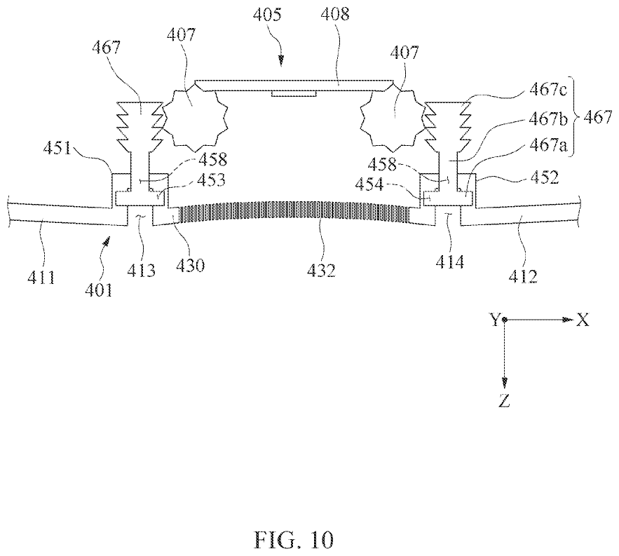

FIG. 10 is a diagram illustrating one of folding states of the foldable sheet 401 according to an embodiment.

Referring to FIG. 10, according to an embodiment, the foldable sheet 401 may include a third bending hole 458 and a pressing pillar 467.

In an embodiment, the third bending hole 458 may be formed by penetrating in an unfolding direction (e.g., a −Z direction) from the bending area 450. Specifically, there may be an external support 405 such as a hinge unit (e.g., the hinge unit 303 in FIG. 3A) disposed to face one side of the foldable sheet 401, and the external support 405 may include a plurality of gears 407 (e.g., the plurality of gears 335 in FIG. 3B) and a support plate 408 supporting the plurality of gears 407. In an embodiment, the support plate 408 may be a center plate (e.g., the center plate 306 in FIG. 3B) of the hinge unit 303.

In an embodiment, the external support 405 may be disposed on one side of the foldable sheet 401, and the plurality of gears 407 may be inserted into a gear shaft (not shown) to rotate to fold or unfold the foldable sheet 401 in a folding direction (e.g., a +Z direction) or in an unfolding direction (e.g., a −Z direction). In this case, the third bending hole 458 may be formed in at least a portion of the first bending area 451 and the second bending area 452, and may be formed by penetrating in a direction (e.g., the −Z direction) from the foldable sheet 401 to the external support 405.

In an embodiment, the pressing pillar 467 may be inserted into the third bending hole 458 to protrude and be fixed in a direction (e.g., the −Z direction) perpendicular to the foldable sheet 401. The pressing pillar 467 may be fixed to the bending area 450 and may move based on a folded state of the foldable sheet 401, and may contact the plurality of gears 407 of the external support 405 when the foldable sheet 401 is in an unfolded state as shown in FIG. 10.

In an embodiment, the pressing pillar 467 may include a fixing area 467a that is inserted into the third bending hole 458 and fixed to the bending area 450, a pillar area 467b that extends from the fixing area 467a toward the external support 405, and a pressing area 467c that is connected to an outer circumferential surface of the pillar area 467b to press the pillar area 467b.

In an embodiment, the pressing area 467c of the pressing pillar 467 may selectively contact a gear 407, which is the external support 405, and the pressing pillar 467 may then be pressed by the gear 407 to prevent a crease from being generated on the foldable sheet 401, and may be adjacent to the bending area 450 to suppress the foldable sheet 401 from rising.

Specifically, when the foldable sheet 401 is in the folded state, the gear 407 and the pressing area 467c may be spaced apart from each other, and when the foldable sheet 401 is in the unfolded state, the gear 407 and the pressing area 467c may contact each other. By an unfolding operation of the foldable sheet 401 being in the folded state, the pressing area 467c of the pressing pillar 467 may contact the gear 407 and receive a pressure in a downward direction (e.g., the +Z direction). The pressing area 467c may transfer the pressure to the fixing area 467a, and a fixing pillar may then press the bending area 450, thereby suppressing the rise of the bending area 450 or the foldable sheet 401 and preventing creases.

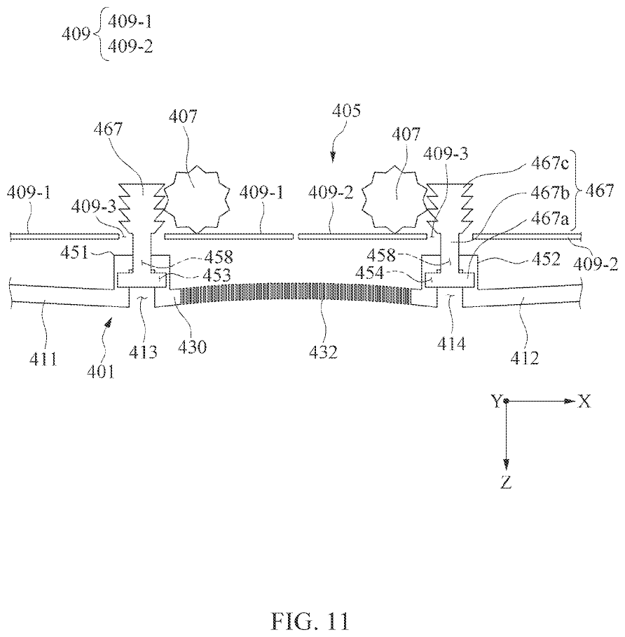

FIG. 11 is a diagram illustrating one of folding states of the foldable sheet 401 according to an embodiment.

Referring to FIG. 11, according to an embodiment, a hinge plate 409 may include a first plate 409-1, a second plate 409-2, and a hole 409-3.

In an embodiment, the external support 405 may be a hinge unit (e.g., the hinge unit 303 in FIG. 3A) including a gear 407. In this case, the hinge plate 409 (e.g., the hinge plate 305 in FIG. 3B) may be movably disposed on both sides by the gear 407 and may include the first plate 409-1 and the second plate 409-2 (e.g., the first plate 305a and the second plate 305b in FIG. 3B). Hereinafter, what has already been described above will be omitted, and the hinge plate 409 and the pressing pillar 467 will be described in greater detail.

In an embodiment, the pressing pillar 467 may be inserted into the third bending hole 458 to protrude and be fixed in a direction (e.g., a −Z direction) perpendicular to the foldable sheet 401, and may be formed by penetrating through the hole 409-3. The pressing pillar 467 may pass through the hole 409-3 with the foldable sheet 401 unfolded to come into contact with a plurality of gears 407 disposed in an opposite direction (e.g., the −Z direction) with respect to the hinge plate 409.

In an embodiment, of the pressing pillar 467, the pillar area 467b extending toward the external support 405 may be disposed in the hole 409-3. Based on the pillar area 467b, the pressing area 467c may be disposed in a direction of the external support 405 (e.g., the −Z direction), and the fixing area 467a may be disposed in a direction of the foldable sheet 401 (e.g., the +Z direction).

In an embodiment, the pressing area 467c of the pressing pillar 467 may selectively contact the gear 407 to press the foldable sheet 401 to prevent creases on the foldable sheet 401, and may be adjacent to the bending area 450 to suppress the rise of the foldable sheet 401. Specifically, as the foldable sheet 401 is folded, the hinge plate 409 that moves in conjunction with the foldable sheet 401 may move away from the gear 407, and a space may therefore be provided. In an embodiment, when the foldable sheet 401 is in a folded state, the pressing pillar 467 may be disposed in the space formed between the gear 407 and the hinge plate 409, and when the foldable sheet 401 is in an unfolded state, may be pressed by the gear 407 to transfer the pressure to the fixing area 467a and press the foldable sheet 401.

According to an embodiment of the present disclosure, a foldable sheet 401 may include: a body area 410 including a first body 411 and a second body 412 spaced apart from the first body 411; a folding area 430 disposed between the first body 411 and the second body 412 and configured to be folded in a first direction such that the first body 411 and the second body 412 face each other; and a bending area 450 including a first bending area 451 connecting one end of the folding area 430 and the first body 411 and a second bending area 452 connecting the other end of the folding area 430 and the second body 412. In an embodiment, the bending area 450 may be provided in a structure that is bent at least twice to protrude in a second direction that is opposite to the first direction such that the first body 411 and the second body 412 are arranged in parallel when the folding area 430 is in an unfolded state.

In an embodiment, the first bending area 451 may include a first bending hole 453 formed by penetrating in a direction from the folding area 430 to the first body 411. In an embodiment, the second bending area 452 may include a second bending hole 454 formed by penetrating in a direction from the folding area 430 to the second body 412.

In an embodiment, the foldable sheet 401 may include a center cover 460 disposed on one side of the folding area 430 in the second direction and including a plurality of fasteners 463 configured to be inserted into the first bending hole 453 and the second bending hole 454, respectively, when the folding area 430 is in the unfolded state.

In an embodiment, the center cover 460 may be formed of a material that has greater rigidity than the folding area 430. In an embodiment, the plurality of fasteners 463 of the center cover 460 may be separated from the first bending hole 453 and the second bending hole 454, when the folding area 430 is in a folded state.

In an embodiment, the plurality of fasteners 463 may have a shape whose cross-sectional area decreases while developing in a direction from the center of the center cover 460 to the bending area 450.

In an embodiment, each of the plurality of fasteners 463 may include a lower surface 463a that contacts the bending area 450 in the unfolded state of the folding area 430, and an upper surface 463b that is an opposite surface of the lower surface 463a. In an embodiment, the lower surface 463a may be substantially flat, and the upper surface 463b may be inclined downward in a direction from the center of the center cover 460 to the bending area 450.

In an embodiment, the bending area 450 may include a third bending hole 458 formed by penetrating in the second direction. In an embodiment, the foldable sheet 401 may include a pressing pillar 467 including a fixing area 467a that is inserted into the third bending hole 458 and fixed to the bending area 450, a pillar area 467b extending in the second direction from the fixing area 467a, and a pressing area 467c connected to an outer circumferential surface of the pillar area 467b and selectively contacting an external support 405 to press the pillar area 467b.

In an embodiment, by an operation in which the folding area 430 is unfolded from the folded state, the pressing area 467c of the pressing pillar 467 may contact the external support 405 to press the fixing area 467a.

In an embodiment, the body area 410, the folding area 430, and the bending area 450 may be formed of at least some of a metallic material, a polymeric compound, and a CFRP.

In an embodiment, the body area 410, the folding area 430, and the bending area 450 may be continuous with each other. For example, the body area 410, the folding area 430, and the bending area 450 may be formed as a single continuous body so as to be continuous with each other.

In an embodiment, the bending area 450 may include a plurality of first bending areas 451 and a plurality of second bending areas 452 in a direction surrounding the folding area 430. In an embodiment, the plurality of first bending areas 451 and the plurality of second bending areas 452 may be arranged to be spaced apart from each other, respectively.

According to an embodiment of the present disclosure, an electronic device 301 may include: a hinge unit 303 that is folded in a folding direction and unfolded in an unfolding direction; a pair of housings 490 configured to be coupled to the hinge unit 303 such that they are folded in directions facing each other with respect to the hinge unit 303; and a foldable sheet 401 connected to one side of the pair of housings 490 in the folding direction. In an embodiment, the foldable sheet 401 may include: a body area 410 including a first body 411 and a second body 412 that are spaced apart and connected to the pair of housings 490, respectively; a folding area 430 disposed between the first body 411 and the second body 412 and configured to be folded in conjunction with the hinge unit 303; and a bending area 450 including a first bending area 451 connecting one end of the folding area 430 and the first body 411 and a second bending area 452 connecting the other end of the folding area 430 and the second body 412. In an embodiment, the bending area 450 may be provided in a structure that is bent at least twice to protrude in the unfolding direction such that the first body 411 and the second body 412 are arranged in parallel when the folding area is an unfolded state.

In an embodiment, the first bending area 451 may include a first bending hole 453 formed by penetrating in a direction from the folding area 430 to the first body 411. In an embodiment, the second bending area 452 may include a second bending hole 454 formed by penetrating in a direction from the folding area 430 to the second body 412.

In an embodiment, the foldable sheet 401 may include a center cover 460 disposed between the folding area 430 and the hinge unit 303 and including a plurality of fasteners 463 inserted into the first bending hole 453 and the second bending hole 454, respectively, when the folding area 430 is in the unfolded state.

In an embodiment, the center cover 460 may be formed of a material with greater rigidity than the folding area 430. In an embodiment, the plurality of fasteners 463 of the center cover 460 may be separated from the first bending hole 453 and the second bending hole 454, respectively, when the folding area 430 is in a folded state.

In an embodiment, the plurality of fasteners 463 may have a shape whose cross-sectional area decreases while developing in a direction from the center of the center cover 460 to the bending area 450.

In an embodiment, each of the plurality of fasteners 463 may include a lower surface 463a that contacts the bending area 450 when the folding area 430 is in the unfolded state, and an upper surface 463b that is an opposite surface of the lower surface 463a. In an embodiment, the lower surface 463a may be substantially flat, and the upper surface 463b may be inclined downward in a direction from the center of the center cover 460 to the bending area 450.

In an embodiment, the hinge unit 303 may include a pair of plates 305a and 305b connected to a pair of housings 490, respectively, and spaced apart from each other; and a plurality of gears 407 disposed between the pair of plates 305a and 305b and configured to rotate the pair of plates 305a and 305b in the folding direction. In an embodiment, the center cover 460 may be disposed between the plurality of gears 407 and the foldable sheet 401, and may be coupled to be fixed to the plurality of gears 407.

In an embodiment, the bending area 450 may include a third bending hole 458 formed by penetrating in a direction from the foldable sheet 401 to the hinge unit 303. In an embodiment, the electronic device 301 may include a pressing pillar 467 including a fixing area 467a that is inserted into the third bending hole 458 and fixed to the bending area 450, a pillar area 467b extending in a direction from the fixing area 467a to the hinge unit 303, and a pressing area 467c connected to an outer circumferential surface of the pillar area 467b and configured to selectively contact the hinge unit 303 in conjunction with an unfolding operation of the hinge unit 303 and press the pillar area 467b.

In an embodiment, the body area 410, the folding area 430, and the bending area 450 may include at least some of a metallic material, a polymeric compound, and a CFRP.

In an embodiment, the body area 410, the folding area 430, and the bending area 450 may be continuous with each other. For example, the body area 410, the folding area 430, and the bending area 450 may be formed as a single continuous body so as to be continuous with each other.

In an embodiment, the bending area 450 may include a plurality of first bending areas 451 and a plurality of second bending areas 452 in a direction surrounding the folding area 430. In an embodiment, each of the plurality of first bending areas 451 and the plurality of second bending areas 452 may be arranged to be spaced apart from each other.

While the disclosure has been shown and described with reference to various embodiments thereof, it will be understood that the various embodiments are intended to be illustrative, not limiting. It will further be understood by those skilled in the art that various changes in form and details may be made therein without departing from the true spirit and full scope of the disclosure as defined by the appended claims and their equivalents. It will also be understood that any of the embodiment(s) described herein may be used in conjunction with any other embodiment(s) described herein.

1. A foldable sheet, comprising:
a body area comprising a first body and a second body spaced apart from the first body;
a folding area disposed between the first body and the second body and folded in a first direction such that the first body and the second body face each other in a folded state; and
a bending area comprising a first bending area connecting one end of the folding area and the first body and a second bending area connecting the other end of the folding area and the second body,
wherein the bending area is provided in a structure that is bent at least twice to protrude in a second direction opposite to the first direction to allow the first body and the second body to be arranged in parallel when the folding area is in an unfolded state.

2. The foldable sheet of claim 1, wherein the first bending area comprises a first bending hole penetrating in a direction from the folding area to the first body, and
the second bending area comprises a second bending hole penetrating in a direction from the folding area to the second body.

3. The foldable sheet of claim 2, comprising:
a center cover disposed on one surface of the folding area in the second direction and comprising a plurality of fasteners to be inserted into the first bending hole and the second bending hole, respectively, when the folding area is in the unfolded state.

4. The foldable sheet of claim 3, wherein the plurality of fasteners of the center cover are separated from the first bending hole and the second bending hole, respectively, when the folding area is in a folded state.

5. The foldable sheet of claim 3, wherein the center cover is formed of a material with greater rigidity than the folding area.

6. The foldable sheet of claim 3, wherein the plurality of fasteners is provided in a shape whose cross-sectional area decreases as developing in a direction from a center of the center cover to the bending area.

7. The foldable sheet of claim 3, wherein each of the plurality of fasteners comprises:
a lower surface that contacts the bending area when the folding area is in the unfolded state and an upper surface opposite to the lower surface,
wherein the lower surface is substantially flat, and the upper surface is inclined downward in a direction from a center of the center cover to the bending area.

8. The foldable sheet of claim 1, wherein the bending area comprises:
a third bending hole penetrating in the second direction.

9. The foldable sheet of claim 8, comprising:
a pressing pillar comprising a fixing area that is inserted into the third bending hole and fixed to the bending area, a pillar area extending in the second direction from the fixing area, and a pressing area that is connected to an outer circumferential surface of the pillar area and selectively contacts an external support to press the pillar area.

10. The foldable sheet of claim 9, wherein the pressing pillar is configured to press the fixing area as the pressing area contacts the external support by an operation in which the folding area is unfolded while in the folded state.

11. The foldable sheet of claim 1, wherein the body area, the folding area, and the bending area are provided as a single body in which they are continuous with each other.

12. The foldable sheet of claim 1, wherein the body area, the folding area, and the bending area are formed of at least some of a metallic material, a polymeric compound, or a carbon fiber-reinforced plastic (CFRP).

13. The foldable sheet of claim 1, wherein the bending area comprises:
the first bending area and the second bending area provided respectively as a plurality of first bending areas and a plurality of second bending areas in a direction surrounding the folding area.

14. The foldable sheet of claim 13, wherein the plurality of first bending areas and the plurality of second bending areas are arranged to be spaced apart from each other.

15. An electronic device, comprising:
a hinge unit that is folded in a folding direction and is unfolded in an unfolding direction;
a pair of housings coupled to the hinge unit to be folded in opposite directions with respect to the hinge unit; and
a foldable sheet connected to one surface of the pair of housings in the folding direction,
wherein the foldable sheet comprises:
a body area comprising a first body and a second body spaced apart to be respectively connected to the pair of housings;
a folding area disposed between the first body and the second body and folded in conjunction with the hinge unit; and
a bending area comprising a first bending area connecting one end of the folding area and the first body and a second bending area connecting the other end of the folding area and the second body,
wherein the bending area is provided in a structure that is bent at least twice to protrude in the unfolding direction to allow the first body and the second body to be arranged in parallel when the folding area is unfolded.

16. The electronic device of claim 15, wherein the first bending area comprises a first bending hole formed by penetrating in a direction from the folding area to the first body, and
the second bending area comprises a second bending hole formed by penetrating in a direction from the folding area to the second body.

17. The electronic device of claim 16, wherein the foldable sheet comprises:
a center cover disposed between the folding area and the hinge unit and comprising a plurality of fasteners inserted into the first bending hole and the second bending hole, respectively, when the folding area is unfolded.

18. The electronic device of claim 17, wherein the center cover is formed of a material with greater rigidity than the folding area, and
the plurality of fasteners of the center cover is separated from the first bending hole and the second bending hole, respectively, when the folding area is in a folded state.

19. The electronic device of claim 17, wherein the plurality of fasteners is provided in a shape whose cross-sectional area decreases as developing in a direction from a center of the center cover to the bending area.

20. A foldable sheet, comprising:
a folding area disposed between a first body of the foldable sheet and a second body of the foldable sheet;
a bending area comprising a first bending area connecting one end of the folding area and the first body and a second bending area connecting the other end of the folding area and the second body; and
a first gap between the first body and the bending area, and a second gap between the second body and the bending area.
